(19) United States
(12) Patent Application Publication
(10) Pub. No.: US 2003/0104680 A1
(43) Pub. Date: Jun. 5, 2003

(54) Process for the removal of copper from polished boron-doped silicon wafers

(75) Inventors: Andrei D. Stefanescu, Pittsburgh, PA (US); Leonard O. Rosik, Troy, MO (US); Tina L. Gardner, Wright City, MO (US)

Correspondence Address: SENNIGER POWERS LEAVITT AND ROEDEL, ONE METROPOLITAN SQUARE, 16TH FLOOR, ST LOUIS, MO, 63102, US

(73) Assignee: MEMC Electronic Materials, Inc.

(21) Appl. No.: 10/294,325

(22) Filed: Nov. 13, 2002

Related U.S. Application Data
(60) Provisional application No. 60/338,300, filed on Nov. 13, 2001.

(51) Int. Cl. H01L 21/322

(52) U.S. Cl. 438/471

(57) ABSTRACT

A process of removing metallic impurities from a polished boron-doped silicon wafer comprising forming an oxide layer on the polished wafer that is thicker than a typical native oxide layer so that the oxide layer has a greater gettering capacity than a native oxide layer gettering capacity and then annealing the wafer at a temperature of at least about 75° C. for at least about 30 seconds to decrease the concentration of the metallic impurity in the interior of the silicon wafer and increase the concentration of the metallic impurity on the polished surface of the silicon wafer and in the oxide layer. Preferably, the annealed silicon wafer is cleaned to remove the oxide layer and to remove the metallic impurity from the polished surface of the silicon wafer. By repeatedly creating an oxide layer and annealing the wafer, the wafer can be made substantially free of metallic impurities.

### CROSS-REFERENCE TO RELATED APPLICATIONS

This application claims the benefit of U.S. Provisional Application No. 60/338,300, filed Nov. 13, 2001.

### BACKGROUND OF THE INVENTION

The present invention relates generally to a process for removing contaminant metals (e.g., copper, nickel, aluminum, iron, chromium, etc.) which are present in boron-doped silicon wafers and, more particularly, to a process for diffusing contaminant metals from the bulk to the surface of such wafers from which they can be removed while avoiding the formation of metallic precipitates.

Under appropriate conditions, copper present in a silicon wafer reacts with silicon to form a copper silicide precipitate, sometimes referred to as haze defects because, upon being subjected to a common etching treatment and bright light inspection, such defects appear as a haze on the surface of the wafer. Integrated circuit manufacturers generally require that the concentration of copper on the surface of a silicon wafer be no more than 1×10¹⁰ atoms/cm² to 1×10¹¹ atoms/cm², as determined by methods standard in the art. It is foreseeable that this requirement will be decreased to a value of 5×10⁹ atoms/cm², 1×10⁹ atoms/cm² or less since a large fraction of random device failures can be traced to copper silicide precipitates.

Immediately after wafers have undergone conventional polishing treatments and state of the art cleaning methods, the copper concentration on the surface of the wafers is typically less than 1×10¹⁰ atoms/cm², as determined by total reflection spectroscopy (TXRF) measurements. See, e.g., C. Neumann et al., Spectrochemica Acta, 10 (1991), pp.1369-1377; and Ingle & Crouch, Spectrochemical Analysis, Prentice Hall, 1988. The surface copper concentration of these wafers, however, tends to increase with the passage of time even at room temperature until saturation is reached. Thus, wafers which meet a target specification for surface copper concentration immediately after cleaning may fail to meet this specification as soon as five to ten months later.

Intrinsic gettering has been used in an attempt to trap copper and other metals and prevent these contaminants from reaching the device region of the wafer. Such an approach has not proven to be entirely effective for copper, however, due to the high diffusivity of copper in silicon which makes it possible for copper to escape from the gettering sites and reach the device region of the wafer.

Another technique for dealing with copper contamination involves subjecting a boron-doped wafer to a low temperature anneal for a relatively short period of time to increase the rate at which the copper-dopant complexes dissociate and the copper diffuses to the surface of the wafer. The surfaces of the wafer are then cleaned to remove the copper. See Falster et al., U.S. Pat. No. 6,100,167.

In addition to controlling the concentration copper impurities, it is desirable to determine the degree of copper contamination in a silicon wafer. Secondary ion mass spectroscopy (SIMS), Neutron Activation and acid digestion/spectroscopy have been used to determine the concentration of metallic impurities, however, each process is less than ideal for a wafer manufacturing setting. For example, although SIMS and Neutron Activation are relatively accurate, they are expensive, time consuming and impractical for routine testing. Acid digestion/spectroscopy is less expensive, but it is much less accurate.

Ohta et al. (U.S. Pat. No. 6,174,740 B1) proposed a method similar to extrinsic gettering to analyze impurity metals such as copper in a silicon wafer. The method comprises: damaging a major surface of the wafer by sandblasting to form a layer of surface distortions; subjecting the wafer to a thermal oxidation process to form a thermal oxide film on the distorted layer; dissolving the oxide film and the layer of surface distortions with a solution; and recovering and analyzing the solution for impurities. Ohta et al., indicate that the thermal oxide layer covers or caps the distorted layer and the thermal energy promotes the migration of impurities to the distorted layer where they are captured. The method proposed by Ohta et al., however, damages the silicon wafer, requires additional equipment (i.e., an apparatus for sandblasting) and would most likely require that the wafer be re-polished and re-cleaned before being used to manufacture an integrated circuit.

Therefore, a need continues to exist for a process which allows for a more complete removal of copper from polished, boron-doped silicon wafers and for a process of accurately determining the concentration of copper in such wafers without damaging or destroying the wafers.

### SUMMARY OF THE INVENTION

Among the objects of the present invention, therefore, is the provision of a process which removes substantially all of the metallic impurities including copper from polished, boron-doped silicon wafers; the provision of a process for accurately determining the concentration of copper in such wafers; the provision of a relatively quick and inexpensive method for determining the concentration of copper in silicon wafers; the provision of a process which does not damage or destroy the treated wafers; and the provision of a process which allows treated wafers to be stored for a duration of 5 months or longer with the surface of the wafer being substantially free of copper.

Briefly, therefore, the present invention is directed to a process of gettering a metallic impurity in a boron-doped silicon wafer having a polished surface. The process comprises forming an oxide layer on the polished surface that is thicker than a typical native oxide layer and thereby has a metallic impurity gettering capacity greater than a typical native oxide layer gettering capacity. The wafer is also annealed at a temperature of at least about 75° C. for at least about 30 seconds to decrease the concentration of the metallic impurity in the interior of the silicon wafer and increase the concentration of the metallic impurity on the polished surface of the silicon wafer and in the oxide layer.

The present invention is also directed to a process of treating a boron-doped silicon wafer having a polished surface to decrease the concentration of a metallic impurity in the interior of the silicon wafer and on the polished surface. The process comprises forming an oxide layer on the polished surface that is thicker than a typical native oxide layer and thereby has a metallic impurity gettering capacity greater than a typical native oxide layer gettering capacity. The silicon wafer is annealed at a temperature of at least about 75° C. for at least about 30 seconds to decrease the concentration of the metallic impurity in the interior of the silicon wafer and increase the concentration of the metallic impurity on the polished surface of the silicon wafer and in the oxide layer. Then, the annealed silicon wafer is cleaned to remove the oxide layer and to remove the metallic impurity from the polished surface of the silicon wafer.

The present invention is also directed to a process for determining the concentration of copper in a boron-doped silicon wafer having a polished surface. The process comprises:

a. forming an oxide layer on the polished surface that is thicker than a typical native oxide layer and thereby has a metallic impurity gettering capacity greater than a typical native oxide layer gettering capacity;

b. annealing the silicon wafer at a temperature of at least about 75° C. for at least about 30 seconds to decrease the concentration of copper in the interior of the silicon wafer and increase the concentration of copper on the polished surface of the silicon wafer and in the oxide layer;

c. contacting the silicon wafer with a chemical solution to dissolve the oxide layer and remove copper from the polished surface of the silicon wafer;

d. measuring the amount of copper in the chemical solution;

e. repeating steps a-d until the chemical solution is substantially free of copper; and

f. summing the amounts of copper measured from each iteration of step d to determine the concentration of copper in the silicon wafer.

Other objects and features of this invention will be in part apparent and in part pointed out hereinafter.

### BRIEF DESCRIPTION OF THE DRAWINGS

FIG. 1 is a graph that depicts the concentration of copper on the surfaces of polished, boron-doped silicon wafers subjected to a low temperature anneal for a duration of about 4 hours and about 12 hours as described in Example 1.

FIG. 2 is a graph that depicts the concentration of copper on the surfaces of polished, boron-doped silicon wafers after a low temperature anneal and after the oxide formation-low temperature anneal method of the present invention as described in Example 2.

FIG. 3 is a graph that depicts the cumulative copper concentrations on the surfaces of polished, boron-doped silicon wafers subjected to the oxide formation-low temperature anneal method of the present invention as described in Example 2.

FIG. 4 is a graph that depicts the copper concentrations on the surfaces of polished, boron-doped silicon wafers after a single low temperature anneal, 58 days after a single low temperature anneal, after a oxide formation-low temperature anneal, and the total estimated copper concentration as described in Example 3.

### DETAILED DESCRIPTION OF THE PREFERRED EMBODIMENTS

The following discussion focuses on copper contamination in silicon; copper being the most studied and typically the most problematic of the metallic contaminants. The methods described herein with respect to copper, however, are also applicable to other metallic contaminants found in silicon (e.g., nickel, iron, aluminum, chromium, etc).

Without being bound to any particular theory, it is believed that copper forms some sort of complex with boron and is incorporated or “stored” in this form in boron-doped silicon wafers. It is additionally believed that these copper-boron complexes are metastable, even at room temperature. As time passes, therefore, these complexes dissociate allowing copper to assume an interstitial position. Copper is a rapid diffuser in silicon; the most rapid of all metals and is very mobile even at room temperature. In addition its solubility in silicon is strongly temperature dependent and at low temperatures, e.g., room temperature, it is very low. At low temperatures, therefore, interstitial copper will rapidly diffuse to the surface of the wafer.

The increase in the concentration of copper on the surface of a wafer as a function of time depends, in part, upon the amount of copper which is contributed by the polishing process and, in part, upon the boron concentration of the wafer. Specifically, as the boron concentration of the wafer increases, the “storage” capacity for copper within the wafer increases.

As noted above, Falster et al. disclose that the rate at which copper contamination within the bulk of a boron-doped silicon wafer diffuses to the surface of the wafer may be significantly increased by subjecting the wafer to a low temperature anneal for a relatively short period of time. In accordance with the present invention it has been discovered that the gettering ability at the surface of a conventional polished silicon wafer with a native oxide layer cannot take full advantage of the increased copper diffusivity. Stated another way, the saturation concentration for copper at the surface of a conventional polished silicon wafer is significantly below that necessary to getter substantially all of the copper within the wafer bulk.

It has been discovered that the ability to getter copper on the surface of a polished silicon wafer depends, in large part, on the presence of oxide on the surface. More specifically, it has been discovered that increasing the thickness of oxide on the surface of a wafer improves the ability to getter copper (i.e., increases the saturation concentration). In accordance with the present invention, an oxide layer is formed, deposited, or grown on a polished surface of a boron-doped silicon wafer prior to and/or during a low temperature anneal to out diffuse copper from the bulk of the wafer, wherein the oxide layer has a thickness that is greater than that of a typical native oxide layer and thereby has a metallic impurity gettering capacity greater than a native oxide layer gettering capacity. The present invention is particularly useful for the manufacture of double side polished wafers which are required to have a specular gloss finish on both major surfaces of the wafer. Preferably, the process is carried out immediately after polishing and before any silicon wafer processing step in which the wafers are heated to a temperature in excess of 500° C.

In general, the process of the present invention is carried out on polished wafers, i.e., wafers having a bare silicon face (except for a native silicon dioxide layer which forms when the wafer is exposed to air at, e.g., room temperature for an indefinite period of time and is typically about 15 Å thick) which has been polished to provide a specular finish thereon and not on patterned wafers, i.e., wafers onto which an organic material, metal or other material has been deposited or otherwise formed on less than the entire surface of the wafer using a mask or other comparable means. As a result, the process of forming an oxide layer on the polished surface of a silicon wafer typically comprises forming a supplemental oxide layer (e.g., a layer of oxide with a thickness greater than about 6 Å) on the native oxide layer supplemental oxide layer. If this is the case, the oxide layer comprises the native oxide layer and the supplemental oxide layer thereon. It is possible, however, that the oxide layer may not comprise a native oxide layer. Specifically, the native oxide layer may be removed or for some other reason absent, and as a result the oxide layer comprises a supplemental oxide layer. This situation could result, for example, during the process of the present invention when an oxide layer is formed on the wafer after a previously annealed wafer was cleaned to remove a previously formed oxide layer containing gettered metallic impurities (see, infra). Regardless of whether or not a native oxide layer is present, the oxide layer formed on the wafer has a thickness that is greater than that of a typical native oxide layer.

In one embodiment of the present invention, the polished silicon wafer is subjected to a gas-phase oxidation step which employs an oxygen-containing gas to grow the supplemental oxide layer on the surface of the wafer. Specifically, for example, the polished surface of the wafer is subjected to ozonolysis by contacting the surface of the wafer with gas comprising ozone. For reasons of simplicity and cost, the gas preferably comprises air and ozone. The ozone may be added to the ambient by any appropriate method such as an ozone generator (e.g., a GTC-0.5C available from Ozonia of Lodi, N.J.). The wafer is exposed to the ozonated ambient for a duration sufficient to grow a supplemental oxide layer having a thickness of greater than about 6 Å. Preferably, the wafer is exposed to the ozonated ambient for a duration sufficient to grow a supplemental oxide layer having a thickness between about 6 and about 20 Å, more preferably between about 8 and about 12 Å, and still more preferably about 10 Å. For example, exposing a wafer to an ambient comprising between about 0.5 and about 1.0% by weight ozone in dry air for a duration of between about 10 and about 30 minutes produces a supplemental oxide layer that is between about 8 and about 12 Å thick.

In another preferred embodiment, the supplemental oxide layer may be formed on the surface of the silicon wafer by a liquid-phase oxide deposition step. For example, spin-on glass layers comprising silicon oxide may be deposited on a polished surface of a wafer. Spin-on glass layers are typically used to manufacture integrated circuits and are usually based on tetraalkyl siloxanes or silsequioxane derivatives. The use of a spin-on glass layer to deposit silicon oxide on the polished wafer surface is presently believed to be particularly beneficial in the formation of a supplemental oxide layer that exceeds about 20 Å. For example, spin-on glass layers between about 20 and about 50 Å thick are typically produced during integrated circuit manufacturing.

During or after the formation of the supplemental oxide layer, the wafer is subjected to a low temperature anneal to out diffuse the copper in the wafer bulk into the supplemental oxide layer on the surface. In general, temperatures of less than about 500° C. are preferred for the annealing step of the present invention. At substantially greater temperatures, e.g., temperatures in excess of about 600° C., the copper-dopant complexes dissociate and the newly released copper will typically be present in the silicon below its solubility limit. As the wafer is cooled from 600° C., however, the solubility of copper in silicon rapidly decreases and, if there is sufficient copper present, energy barriers will be overcome and it will precipitate. At temperatures in the range of 500° C. and less, the copper-dopant complexes dissociate and the copper is released into silicon in which it is typically not soluble. As a result, the copper rapidly diffuses to the surface of the wafer without forming a precipitate. Stated another way, the energy barrier for the precipitation reaction is never exceeded and the copper is present on the surface of the wafer in a form in which it, like other copper surface contaminants, can be cleaned from the surface using standard, state-of-the-art cleaning chemistries.

The duration of the annealing step is a function of the annealing temperature, with the time and temperature being selected to achieve the desired effect, i.e., diffusion of a sufficient quantity of copper to the surface of the silicon wafer from the wafer bulk (e.g., regions of the wafer which are at distances more than 5 micrometers from the surface of wafer). For a given copper concentration, a higher anneal temperature will require a shorter annealing time; likewise, a lower anneal temperature will require a longer annealing time.

Typically, the polished, boron-doped wafers are annealed at one or more temperatures within the range of about 75 to about 500° C. for a duration between about 30 seconds and about 10 hours, or longer. The preferred temperature and duration of the annealing step for polished wafers with known, or at least shared copper and surface oxide characteristics may be determined empirically by annealing the wafers at a range of temperatures for varying lengths of time, cleaning the surface of the wafers to remove copper which is present, and determining the concentration of copper on the surface of the wafers. Although substantially increasing the duration of the annealing step (e.g., from about 4 hours to about 15 hours) generally increases the amount of copper out diffused to the wafer surface, eventually the oxide layer becomes saturated and the concentration of copper at the surface ceases to increase appreciably. Experience to date suggests that the wafers are preferably annealed at a temperature between about 100 and about 200° C. for a duration between about 0.5 and about 5 hours. When a shorter annealing time is desired (e.g., between about 5 minutes and about 1.5 hours), the temperature is preferably between about 225 and about 300° C.

The wafers may be annealed in a furnace, preferably a tube furnace. Depending upon the temperature range that is to be employed with the present process, however, heated rooms may also be used. The low temperature anneal process is typically carried out under an inert gas atmosphere, preferably a nitrogen atmosphere. An inert atmosphere, however, is not required and experience has shown that air is also acceptable. Alternatively, the low temperature anneal may be carried out concurrently with the formation of the supplemental oxide layer in an oxidizing gas.

Alternatively, the wafers may be annealed while immersed in a liquid. When a temperature of up to about 100° C. is desired, water may be used as the liquid. Experience has shown that the only limitations on the type of solution which may be used in the present low temperature annealing step is that the solution must not roughen or otherwise materially degrade the finish of the wafer.

After the low temperature anneal step is complete, the wafer is subjected to a cleaning step which effectively removes copper to a surface concentration of less than about 1×10¹⁰ atoms/cm², preferably less than about 5×10⁹ atoms/cm², and more preferably less than about 1×10⁹ atoms/cm². Typical cleaning solutions include piranha mixtures (mixtures of sulfuric acid and hydrogen peroxide), RCA-type SC-1 and SC-2 cleaning solutions (see, e.g., F. Shimura, Semiconductor Silicon Crvstal Technology, Academic Press, 1989, pp. 188-191 and Appendix XII, incorporated herein by reference). The wafers may be immersed in the cleaning solution, or alternatively, exposed to scrubbing jets.

An RCA-type SC-1 solution removes organic contaminants and particles by both the solvating action of ammonium hydroxide and the powerful oxidizing action of hydrogen peroxide; typical SC-1 cleaning solutions contain between about 1000:1:1 to about 1:1:1 parts by volume H₂O:H₂O₂:NH₄OH (supplied as 30-35 weight percent H₂O₂ in water and 28-30 weight percent NH₄OH in water); that is, the SC-1 cleaning solution contains H₂O, H₂O₂ and NH₄OH and the ratio of H₂O to H₂O₂ (supplied as 30-35 weight percent H₂O₂ in water) is between about 1000:1 and abut 1:1, the ratio of H₂O to NH₄OH (supplied as 28-30 weight percent NH₄OH in water) is between about 1000:1 and 1:1, and the ratio of H₂O to H₂O₂ is independent of the ratio of H₂O to NH₄OH. Preferred SC-1 cleaning solutions comprise about 100:1:1 to about 5:1:1 parts by volume H₂O:H₂O₂:NH₄OH, and have a temperature between about 30 and about 80° C., preferably between about 60 and about 80° C.

The wafers may be cleaned in an SC-1 solution for a duration between about 5 and about 30 minutes. If the wafers are immersed in the cleaning solution for a longer time, excessive etching, pitting and roughening can occur. After cleaning, the wafers are immersed in a rinse bath to quench the reaction and remove the SC-1 cleaner from the wafer surfaces. The wafers are rinsed for a period of about 2 to about 60 minutes, typically from about 5 to about 45 minutes, in deionized water having a resistivity of about 3 to about 18 mega-Ohms, preferably greater than about 17 mega-Ohms.

An RCA-type SC-2 solution typically contains about 1:1 to about 1:10,000 parts by volume HF:H₂O (supplied as 49 weight percent HF in water). To enhance metals removal, the solution may additionally contain HCl (1000:1 to 1:1000 parts by volume HF:HCl), hydrogen peroxide (1:1 to 1:1000 parts by volume HF to H₂O₂), isopropyl alcohol (10,000:1 to 1:10 parts by volume HF:IPA) or ozone (about 0.05 to about 50 ppm). A typical SC-2 bath may contain about 1:1:5 to about 1:1:1000 parts by volume of HCl:H₂O₂:H₂O. The temperature of the HF and SC-2 solutions may be between about 10 and about 90° C., and the silicon wafers are immersed in a flowing bath of this solution for a period of at least about 0.1 minutes. These solutions effectively remove alkali and transition metals, and prevent redeposition from the solution by forming soluble metal complexes.

Because low temperatures are used in the annealing step, the copper which migrates to the surfaces of the wafers exists in its atomic form, rather than as copper silicide precipitates. Unlike these copper precipitates, copper in its atomic form can be easily removed by cleaning methods standard in the art. As a result, wafers which are annealed and then cleaned can have surface copper concentrations of less than about 1×10¹⁰ atoms/cm², preferably less than about 5×10⁹ atoms/cm² and more preferably less than about 1×10⁹ atoms/cm².

In one embodiment of the present invention, copper is removed from a boron-doped silicon wafer having a polished surface (with a native oxide layer) by annealing the wafer at a temperature of at least about 75° C. for at least about 30 seconds to out diffuse copper (i.e., decrease the concentration of copper in the interior of the silicon wafer and increase the concentration of copper on the polished surface of the silicon wafer). The annealed wafer is cleaned to remove the copper from the polished surface of the wafer. After the foregoing first round of copper removal and in accordance with the present invention, an oxide layer having a thickness greater than about 10 Å is grown on the polished surface of the wafer. The wafer is then annealed at a temperature of at least about 75° C. for at least about 30 seconds to out diffuse copper remaining in the wafer bulk to the polished surface of the silicon wafer and in the oxide layer. The annealed silicon wafer is cleaned to remove the oxide layer and to remove copper from the polished surface of the silicon wafer. The process of re-oxidizing the polished surface of the wafer, annealing and cleaning is preferably repeated until the surface of the wafer is substantially free of copper (e.g., less than about 5×10¹⁰ atoms/cm², preferably less than about 2×10¹⁰ atoms/cm², and more preferably less than about 1×10¹⁰ atoms/cm²) immediately following the anneal and before the cleaning which allows for the concentration of copper of the surface of the wafer to remain relatively constant over extended periods (e.g., 5 months or longer).

In one embodiment of the present invention, the concentration of copper in a boron-doped silicon wafer having a polished surface is determined by annealing the wafer at a temperature of at least about 75° C. for at least about 30 seconds to out diffuse copper in the wafer bulk to the polished surface of the silicon wafer. The concentration of copper on the surface of the polished wafer and/or in the oxide layer is determined by any appropriate method. For example, the acid-drop/ICP-MS (inductively coupled plasma-mass spectroscopy) may be used. In general, acid-drop/ICP-MS entails contacting the surface of the wafer with a chemical solution (e.g., a hydrofluoric acid based mixture) to extract the copper by dissolving oxide and copper from the surface, collecting the solution containing the dissolved oxide and copper and measuring the concentration of copper using ICP-MS. The result is converted to a surface copper concentration expressed in number of atoms per square centimeter of the wafer surface. After determining the copper concentration, the wafer surface is re-oxidized by growing an oxide layer preferably having a thickness greater than about 10 Å on the polished surface of the silicon wafer. The re-oxidized silicon wafer is annealed at a temperature of at least about 75° C. for at least about 30 seconds to out diffuse copper from the wafer bulk to the polished surface of the silicon wafer and in the oxide layer. The concentration of copper on the surface of the wafer and/or in the oxide layer is determined as described above. The process of re-oxidizing the polished surface of the wafer, annealing, measuring the copper is preferably repeated until the surface of the annealed wafer is substantially free of copper. The sum of the surface copper concentration measurements is the total concentration of copper in the wafer.

As illustrated by the Examples set forth below, the process of the present invention may be used to reduce the concentration of copper in polished, borondoped silicon wafers. The Examples set forth a limited set of conditions used to achieve the desired results. Accordingly, the Examples should not be interpreted in a limiting sense.

### EXAMPLE 1

In a cleanroom, double-side polished test wafers having resistivities between about 0.005 and 0.010 ohm-cm (p+ silicon wafers) were loaded into two PFA cassettes along with filler wafers sandwiched between the test wafers. The filler wafers were included in the cassette to compensate for temperature and wafer surface vicinity variations during the annealing process. One or more of the filler wafers were p− wafers to monitor possible copper contamination during the process (p− wafers typically contain less than 1×10¹⁰ atoms/cm² of copper thus any copper contamination is the result of systemic contamination, not out diffusion). Each wafer cassette was placed in an oven and a low temperature anneal was performed according to the following steps: the temperature of each cassette was increased from about 80° C. to about 120° C. over a period of about 60 minutes; the first cassette was then held at about 120° C. for about 90 minutes and the second cassette was held for about 9 hours and 30 minutes (570 minutes); and the wafers were allowed to cool from about 120° C. to about 80° C. over a period of about 90 minutes. The annealed test wafers were then subjected to an acid drop extraction which dissolved the silicon oxide on the surface including any metals therein or on the surface. The extract solution was analyzed by Inductively Coupled Plasma-Mass Spectrometry (ICP-MS) to determine the concentration of metals in the extract solution.

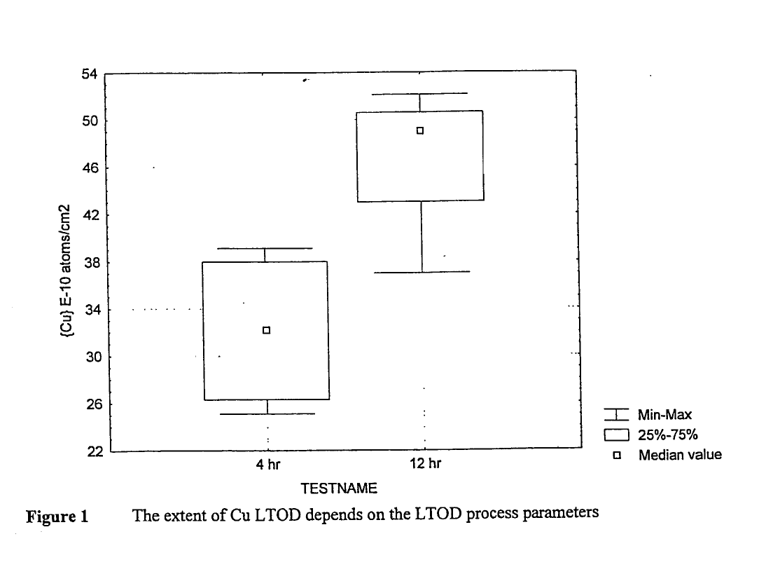

The extent of the out diffusion is variable and strongly dependent on the boron dopant levels, the surface condition of the silicon wafers and anneal process (e.g., duration and temperature). For example, as shown in FIG. 1 the median concentration of copper on the surfaces of the wafers annealed from 4 hours was about 32×10¹⁰ atoms/cm² and for wafers annealed for 12 hours the median concentration of copper on the surfaces of the wafers was about 49×10¹⁰ atoms/cm². The saturation concentration was not reached during the 4 hour anneal, however, after about 8-12 hours the concentration of copper on the surface of the wafers increased very little (i.e., the concentration of copper on the surface and in the native oxide layer had reached a level of saturation).

Although the results set forth above indicate that a significant amount of copper remained in the silicon wafers after the 4 hour anneal, only trace amounts of copper were found on the surfaces of the wafers after being subjected to a second 4 hour anneal (e.g., less than about 1.2×10¹¹ atoms/cm²). This was due to the fact the copper remaining in the bulk of the silicon wafers could not be gettered on the surfaces of the wafers stripped of an oxide layer.

### EXAMPLE 2

Double side polished p+ test wafer pairs sampled from the same lot were annealed for 4 hours and analyzed from copper as set forth above. The pairs were then separated and one wafer was set aside and the second wafer was exposed to a gas stream that contained ozone for about 10 to about 30 minutes. Specifically, the ozone containing gas stream was air containing about 0.5 to about 1.0% O₃ generated at a 20-30 scfh flow-rate and 3 amp current with an OZONIA GTC-0.5C Ozone Generator. The exposure to the ozone containing gas resulted in a supplemental oxide layer on the wafer surface having a thickness of about 10 Å. All the wafers were then combined and subjected to a second anneal.

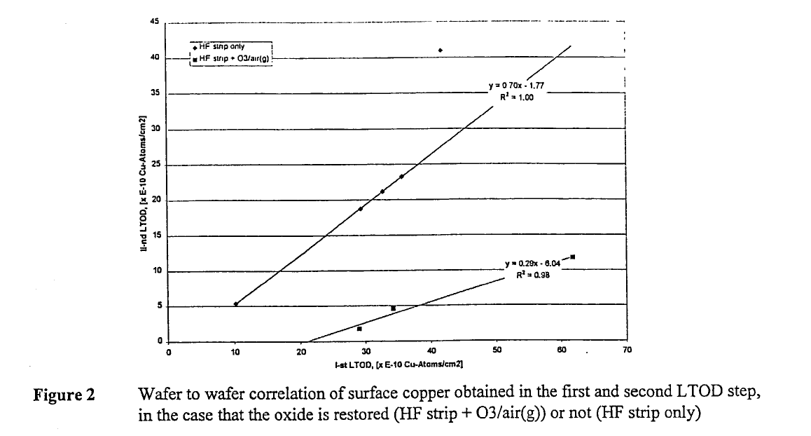

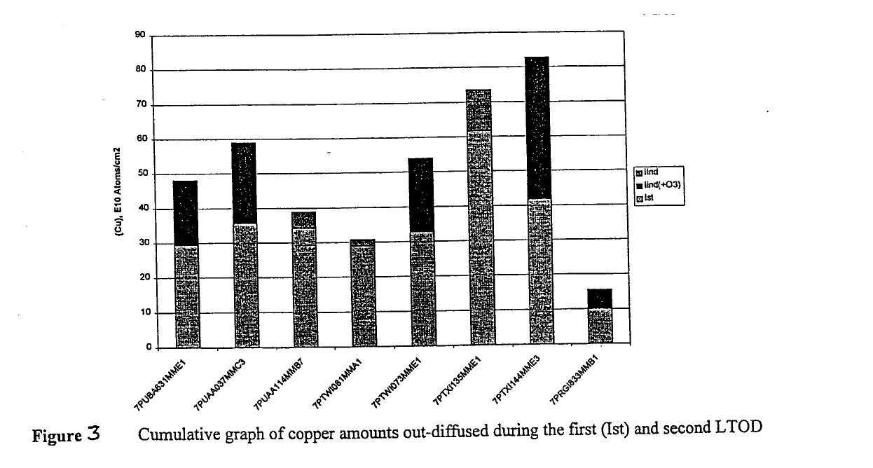

Referring to FIGS. 2 and 3, the results indicate that more copper is gettered and removed from a wafer that is re-oxidized (i.e., has a supplemental oxide layer formed thereon). In fact, the results indicated that less than about 40-60% of the copper is typically out diffused during a standard anneal (i.e., a wafer without a supplemental oxide layer). Thus, this experiment proves: that here is a considerable amount of copper left in the bulk after a single anneal; that the gettering of copper during an anneal is significantly increased by the presence of the supplemental oxide layer; that there is linear correlation between the amounts of copper out diffused by a first anneal and second anneal, regardless of the presence or not of the surface oxide; and that for an oxide layer of a particular thickness there is a saturation concentration of copper after which the surface ceases gettering.

### EXAMPLE 3

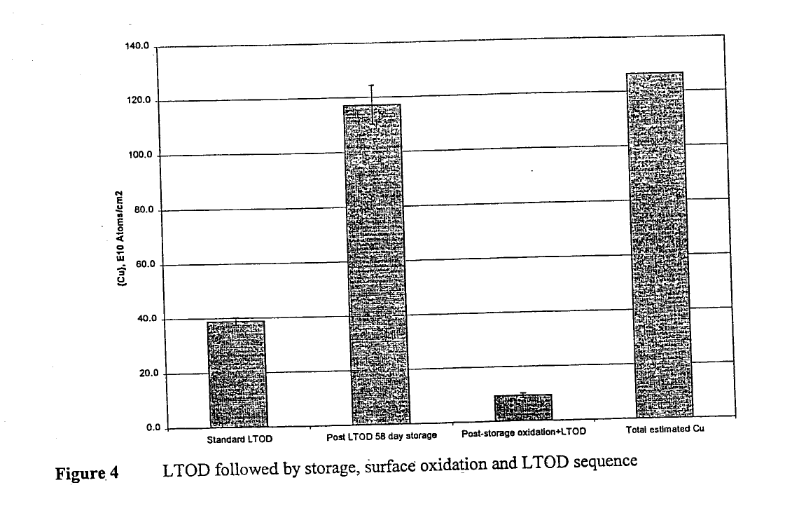

Nine double side polished p+ wafers were subjected to the above described anneal. Referring to FIG. 4, 4 of the wafers were then analyzed for copper and the concentration was about 38×10¹⁰ atoms/cm². The remaining five were repackaged and stored in a cleanroom for a duration of 58 days and then analyzed for copper and the concentration was about 115×10¹⁰ atoms/cm². After being analyzed, these stored wafers were subjected to enhanced oxide formation and then a second anneal. The wafers were then analyzed for copper and the concentration was about 10×10¹⁰ atoms/cm². The small amount of out diffused copper after the formation of the supplemental oxide layer and second anneal suggests that this out diffusion of copper nearly removed substantially all of the copper from the wafer.

As various changes could be made in the above method without departing from the scope of the present invention, it is intended that all matter contained in the above description shall be interpreted as illustrative and not in a limiting sense.

What is claimed is:

1. A process of gettering a metallic impurity in a boron-doped silicon wafer having a polished surface, the process comprising:
forming an oxide layer on the polished surface that is thicker than a typical native oxide layer and thereby has a metallic impurity gettering capacity greater than a typical native oxide layer gettering capacity; and
annealing the silicon wafer at a temperature of at least about 75° C. for at least about 30 seconds to decrease the concentration of the metallic impurity in the interior of the silicon wafer and increase the concentration of the metallic impurity on the polished surface of the silicon wafer and in the oxide layer.

2. The process as set forth in claim 1 wherein the oxide layer comprises a native oxide layer and a supplemental oxide layer on the native oxide layer.

3. The process as set forth in claim 2 wherein the supplemental oxide layer has a thickness of at least about 6 Å.

4. The process as set forth in claim 2 wherein the supplemental oxide layer has a thickness between about 6 and about 20 Å.

5. The process as set forth in claim 2 wherein the forming the oxide layer comprises exposing the wafer to an oxygen-containing gas.

6. The process as set forth in claim 5 wherein the oxygen-containing gas comprises ozone.

7. The process as set forth in claim 5 wherein the oxygen containing gas comprises ozone and air.

8. The process as set forth in claim 7 wherein the supplemental oxide layer has a thickness between about 8 and about 12 Å.

9. The process as set forth in claim 2 wherein forming an oxide layer comprises depositing a liquid-phase oxide.

10. The process as set forth in claim 9 wherein the liquid-phase oxide is a spin-on glass layer comprising silicon oxide.

11. The process as set forth in claim 10 wherein the supplemental oxide layer has a thickness that is at least about 20 Å.

12. The process as set forth in claim 10 wherein the supplemental oxide layer has a thickness between about 20 and about 50 Å.

13. The process as set forth in claim 1 wherein the metallic impurity is selected from the group consisting of copper, nickel, aluminum, iron, chromium and mixtures thereof.

14. The process as set forth in claim 1 wherein the metallic impurity is copper.

15. The process as set forth in claim 1 wherein the temperature of the anneal is less than about 600° C.

16. The process as set forth in claim 1 wherein the temperature of the anneal is less than about 500° C.

17. The process as set forth in claim 1 wherein said annealing the silicon wafer is at a temperature between about 75 and about 500° C. for between about 30 seconds and about 10 hours.

18. The process as set forth in claim 1 wherein said annealing the silicon wafer is at a temperature between about 100 and about 200° C. for between about 0.5 hours and about 5 hours.

19. The process as set forth in claim 1 wherein said annealing the silicon wafer is at a temperature between about 225 and about 300° C. for between about 5 minutes and about 1.5 hours.

20. The process as set forth in claim 1 wherein the polished surface on which the oxide is formed is free of native oxide.

21. A process of treating a boron-doped silicon wafer having a polished surface to decrease the concentration of a metallic impurity in the interior of the silicon wafer and on the polished surface, the process comprising:
a. forming an oxide layer on the polished surface that is thicker than a typical native oxide layer and thereby has a metallic impurity gettering capacity greater than a typical native oxide layer gettering capacity;
b. annealing the silicon wafer at a temperature of at least about 75° C. for at least about 30 seconds to decrease the concentration of the metallic impurity in the interior of the silicon wafer and increase the concentration of the metallic impurity on the polished surface of the silicon wafer and in the oxide layer; and
c. cleaning the annealed silicon wafer to remove the oxide layer and to remove the metallic impurity from the polished surface of the silicon wafer.

22. The process as set forth in claim 21 wherein steps a, b and c are repeated until the oxide layer and the polished surface of the cleaned silicon layer are substantially free of copper.

23. The process as set forth in claim 21 wherein the oxide layer comprises a native oxide layer and a supplemental oxide layer on the native oxide layer.

24. The process as set forth in claim 23 wherein the supplemental oxide layer has a thickness of at least about 6 Å.

25. The process as set forth in claim 23 wherein the supplemental oxide layer has a thickness between about 6 and about 20 Å.

26. The process as set forth in claim 23 wherein the forming the oxide layer comprises exposing the wafer to an oxygen-containing gas.

27. The process as set forth in claim 26 wherein the oxygen-containing gas comprises ozone.

28. The process as set forth in claim 26 wherein the oxygen containing gas comprises ozone and air.

29. The process as set forth in claim 28 wherein the supplemental oxide layer has a thickness between about 8 and about 12 Å.

30. The process as set forth in claim 23 wherein forming an oxide layer comprises depositing a liquid-phase oxide.

31. The process as set forth in claim 30 wherein the liquid-phase oxide is a spin-on glass layer comprising silicon oxide.

32. The process as set forth in claim 31 wherein the supplemental oxide layer has a thickness that is at least about 20 Å.

33. The process as set forth in claim 31 wherein the supplemental oxide layer has a thickness between about 20 and about 50 Å.

34. The process as set forth in claim 21 wherein the metallic impurity is selected from the group consisting of copper, nickel, aluminum, iron, chromium and mixtures thereof.

35. The process as set forth in claim 21 wherein the metallic impurity is copper.

36. The process as set forth in claim 21 wherein the temperature of the anneal is less than about 600° C.

37. The process as set forth in claim 21 wherein the temperature of the anneal is less than about 500° C.

38. The process as set forth in claim 21 wherein said annealing the silicon wafer is at a temperature between about 75 and about 500° C. for between about 30 seconds and about 10 hours.

39. The process as set forth in claim 21 wherein said annealing the silicon wafer is at a temperature between about 100 and about 200° C. for between about 0.5 hours and about 5 hours.

40. The process as set forth in claim 21 wherein said annealing the silicon wafer is at a temperature between about 225 and about 300° C. for between about 5 minutes and about 1.5 hours.

41. The process as set forth in claim 21 wherein the polished surface on which the oxide is formed is free of native oxide.

42. A process of determining the concentration of copper in a boron-doped silicon wafer having a polished surface, the process comprising:
a. forming an oxide layer on the polished surface that is thicker than a typical native oxide layer and thereby has a metallic impurity gettering capacity greater than a typical native oxide layer gettering capacity;
b. annealing the silicon wafer at a temperature of at least about 75° C. for at least about 30 seconds to decrease the concentration of copper in the interior of the silicon wafer and increase the concentration of copper on the polished surface of the silicon wafer and in the oxide layer;
c. contacting the silicon wafer with a chemical solution to dissolve the oxide layer and remove copper from the polished surface of the silicon wafer;
d. measuring the amount of copper in the chemical solution;
e. repeating steps a-d until the chemical solution is substantially free of copper; and
f. summing the amounts of copper measured from each iteration of step d to determine the concentration of copper in the silicon wafer.

43. The process as set forth in claim 42 wherein the oxide layer comprises a native oxide layer and a supplemental oxide layer on the native oxide layer.

44. The process as set forth in claim 43 wherein the supplemental oxide layer has a thickness of at least about 6 Å.

45. The process as set forth in claim 43 wherein the supplemental oxide layer has a thickness between about 6 and about 20 Å.

46. The process as set forth in claim 43 wherein the forming the oxide layer comprises exposing the wafer to an oxygen-containing gas.

47. The process as set forth in claim 46 wherein the oxygen-containing gas comprises ozone.

48. The process as set forth in claim 46 wherein the oxygen containing gas comprises ozone and air.

49. The process as set forth in claim 48 wherein the supplemental oxide layer has a thickness between about 8 and about 12 Å.

50. The process as set forth in claim 43 wherein forming an oxide layer comprises depositing a liquid-phase oxide.

51. The process as set forth in claim 50 wherein the liquid-phase oxide is a spin-on glass layer comprising silicon oxide.

52. The process as set forth in claim 51 wherein the supplemental oxide layer has a thickness that is at least about 20 Å.

53. The process as set forth in claim 51 wherein the supplemental oxide layer has a thickness between about 20 and about 50 Å.

54. The process as set forth in claim 42 wherein the metallic impurity is selected from the group consisting of copper, nickel, aluminum, iron, chromium and mixtures thereof.

55. The process as set forth in claim 42 wherein the metallic impurity is copper.

56. The process as set forth in claim 42 wherein the temperature of the anneal is less than about 600° C.

57. The process as set forth in claim 42 wherein the temperature of the anneal is less than about 500° C.

58. The process as set forth in claim 42 wherein said annealing the silicon wafer is at a temperature between about 75 and about 500° C. for between about 30 seconds and about 10 hours.

59. The process as set forth in claim 42 wherein said annealing the silcon wager is at a temperature between about 100 and about 200° C. for between about 0.5 hours and about 5 hours.

60. The process as set forth in claim 42 wherein said annealing the silicon wafer is at a temperature between about 225 and about 300° C. for between about 5 minutes and about 1.5 hours.

61. The process as set forth in claim 42 wherein the polished surface on which the oxide is formed is free of native oxide.
